(19) United States
(12) Patent Application Publication
(10) Pub. No.: US 2012/0234390 A1
(43) Pub. Date: Sep. 20, 2012

(54) METHOD AND SYSTEM FOR INTEGRATED SOLAR CELL USING A PLURALITY OF PHOTOVOLTAIC REGIONS

(75) Inventor: Kevin R. GIBSON, Redwood City, CA (US)

(73) Assignee: Solaria Corporation, Fremont, CA (US)

(21) Appl. No.: 13/482,949

(22) Filed: May 29, 2012

Related U.S. Application Data
(63) Continuation of application No. 11/445,933, filed on Jun. 2, 2006.
(60) Provisional application No. 60/688,077, filed on Jun. 6, 2005.

(51) Int. Cl. H01L 31/0232; H01L 31/18; H01L 31/048

(52) U.S. Cl. 136/259; 438/64; 438/69; 257/E31.117; 257/E31.127

(57) ABSTRACT

A solar cell device has a back cover member, which includes a surface area and a back area, and a plurality of photovoltaic regions disposed overlying the surface area of the back cover member. The plurality of photovoltaic regions may occupy a total photovoltaic spatial region. The device has an encapsulating material overlying a portion of the back cover member and a front cover member coupled to the encapsulating material. An interface region is provided along at least a peripheral region of the back cover member and the front cover member. A sealed region is formed on at least the interface region to form an individual solar cell from the back cover member and the front cover member. The total photovoltaic spatial region/the surface area of the back cover may be at a ratio of about 0.80 and less for the individual solar cell.

### CROSS-REFERENCES TO RELATED APPLICATIONS

This application is a continuation of U.S. Non-provisional application Ser. No. 11/445,933 (Attorney Docket Number 906R0-000210US) filed Jun. 2, 2006, which claims priority to U.S. Provisional Application No. 60/688,077 (Attorney Docket Number 906R0-000200US) filed Jun. 6, 2005, both of which are incorporated by reference.

This application is also related to U.S. Non-provisional application Ser. No. 11/354,530 (Attorney Docket Number 906RO-000310US) filed Feb. 14, 2006, in the name of Suvi Sharma et al., which claims priority to U.S. Provisional Application No. 60/672,815 (Attorney Docket Number 906RO-000100US) filed Apr. 18, 2005, in the name of Kevin R. Gibson and U.S. Provisional Application No. 60/702,728 filed Jul. 26, 2005 (Attorney Docket Number 025902-000300US) filed Jul. 26, 2005, in the name of Kevin R. Gibson, all of which are incorporated by reference.

This application is also related to U.S. Non-provisional application Ser. No. 11/252,399 (Attorney Docket Number 906RO-001100US) filed Oct. 17, 2005, in the name of Alelie Funcell, which is incorporated by reference.

### BACKGROUND OF THE INVENTION

The present invention relates generally to solar energy techniques. In particular, the present invention provides a method and resulting device fabricated from a plurality of photovoltaic regions provided within one or more substrate members. More particularly, the present invention provides a method and resulting device for manufacturing the photovoltaic regions within the substrate member, which is coupled to a plurality of concentrating elements. Merely by way of example, the invention has been applied to solar panels, commonly termed modules, but it would be recognized that the invention has a much broader range of applicability.

As the population of the world increases, industrial expansion has lead to an equally large consumption of energy. Energy often comes from fossil fuels, including coal and oil, hydroelectric plants, nuclear sources, and others. As merely an example, the International Energy Agency projects further increases in oil consumption, with developing nations such as China and India accounting for most of the increase. Almost every element of our daily lives depends, in part, on oil, which is becoming increasingly scarce. As time further progresses, an era of “cheap” and plentiful oil is coming to an end. Accordingly, other and alternative sources of energy have been developed:

Concurrent with oil, we have also relied upon other very useful sources of energy such as hydroelectric, nuclear, and the like to provide our electricity needs. As an example, most of our conventional electricity requirements for home and business use comes from turbines run on coal or other forms of fossil fuel, nuclear power generation plants, and hydroelectric plants, as well as other forms of renewable energy. Often times, home and business use of electrical power has been stable and widespread.

Most importantly, much if not all of the useful energy found on the Earth comes from our sun. Generally all common plant life on the Earth achieves life using photosynthesis processes from sun light. Fossil fuels such as oil were also developed from biological materials derived from energy associated with the sun. For human beings including “sun worshipers,” sunlight has been essential. For life on the planet Earth, the sun has been our most important energy source and fuel for modern day solar energy.

Solar energy possesses many characteristics that are very desirable! Solar energy is renewable, clean, abundant, and often widespread. Certain technologies developed often capture solar energy, concentrate it, store it, and convert it into other useful forms of energy.

Solar panels have been developed to convert sunlight into energy. As merely an example, solar thermal panels often convert electromagnetic radiation from the sun into thermal energy for heating homes, running certain industrial processes, or driving high grade turbines to generate electricity. As another example, solar photovoltaic panels convert sunlight directly into electricity for a variety of applications. Solar panels are generally composed of an array of solar cells, which are interconnected to each other. The cells are often arranged in series and/or parallel groups of cells in series. Accordingly, solar panels have great potential to benefit our nation, security, and human users. They can even diversify our energy requirements and reduce the world's dependence on oil and other potentially detrimental sources of energy.

Although solar panels have been used successful for certain applications, there are still certain limitations. Solar cells are often costly. Depending upon the geographic region, there are often financial subsidies from governmental entities for purchasing solar panels, which often cannot compete with the direct purchase of electricity from public power companies. Additionally, the panels are often composed of silicon bearing wafer materials. Such wafer materials are often costly and difficult to manufacture efficiently on a large scale. Availability of solar panels is also somewhat scarce. That is, solar panels are often difficult to find and purchase from limited sources of photovoltaic silicon bearing materials. These and other limitations are described throughout the present specification, and may be described in more detail below.

From the above, it is seen that techniques for improving solar devices is highly desirable.

### BRIEF SUMMARY OF THE INVENTION

According to the present invention, techniques related to solar energy are provided. In particular, the present invention provides a method and resulting device fabricated from a plurality of photovoltaic regions provided within one or more substrate members. More particularly, the present invention provides a method and resulting device for manufacturing the photovoltaic regions within the substrate member, which is coupled to a plurality of concentrating elements. Merely by way of example, the invention has been applied to solar panels, commonly termed modules, but it would be recognized that the invention has a much broader range of applicability.

In a specific embodiment, the present invention provides a method for fabricating a solar cell, which may be free and separate from a solar panel. Alternatively, the solar cell may be packaged as a solar panel. In a preferred embodiment, the method forms the solar cell separate from the panel. One or more solar cells are then assembled onto the panel to complete the solar panel device according to a specific embodiment. The method includes providing a first substrate member comprising a plurality of photovoltaic strips thereon and providing an optical elastomer material overlying a portion of the first substrate member. The method also includes aligning a second substrate member comprising a plurality of optical concentrating elements thereon such that at least one of the optical concentrating elements is operably coupled to at least one of the one of the plurality of photovoltaic strips, e.g., regions. The method includes coupling the first substrate member to the second substrate member to form an interface region along a peripheral region of the first substrate member and the second substrate member. In a preferred embodiment, the coupling is provided by joining the substrates with the elastomer material in between them. The method also includes sealing the interface region to form an individual solar cell from at least the first substrate and the second substrate.

In an alternative specific embodiment, the invention includes a method for fabricating another solar cell. The method includes providing a first substrate member comprising a plurality of photovoltaic regions thereon. In a preferred embodiment, the photovoltaic regions can be strips, squares, trapezoids, annular regions (of symmetry or non-symmetry), or any combination of these, and other shapes. The method includes providing an encapsulating material overlying a portion of the first substrate member. The method includes aligning a second substrate member to the first substrate member. The method couples the first substrate member to the second substrate member to form an interface region along a peripheral region of the first substrate member and the second substrate member. The method seals the interface region to form an individual solar cell structure from the first substrate and the second substrate.

In yet still an alternative embodiment, the present invention provides a solar cell device. The device has a first substrate member and a plurality of photovoltaic strips overlying the first substrate member. The device also has an optical elastomer material overlying a portion of the first substrate member and has a second substrate member comprising a plurality of optical concentrating elements thereon. The second substrate member is overlying a the plurality of photovoltaic strips such that at least one of the optical concentrating elements is operably coupled to at least one of the one of the plurality of photovoltaic strips. The device has an interface region along a peripheral region of the first substrate member and the second substrate member. The device also has a sealed region at the interface region to form an individual solar cell from the first substrate member and the second substrate member.

Still further, the present invention provides yet an alternative solar cell device structure. The device structure has a first substrate member, which has spatial region A1, which may be defined as a first area given in units', e.g., centimeters'. In a preferred embodiment, the first square area relates to a surface region of the first substrate member. The device also has a plurality of photovoltaic regions overlying the first substrate member. The plurality of photovoltaic regions are occupying a total photovoltaic spatial region A(2), which may be defined as a second square area. The device has an encapsulating material overlying a portion of the first substrate member and has a second substrate member coupled to the encapsulating material. The device has an interface region along a peripheral region of the first substrate member and the second substrate member and a sealed region at the interface region to form an individual solar cell from the first substrate member and the second substrate member. In a preferred embodiment, the device is characterized by a ratio of A(2)/A(1) that is about 0.80 and less for the individual solar cell.

Still further, the present invention provides an alternative solar cell device structure. The device structure has a back cover member, which includes a surface area and a back area. The device structure also has a plurality of photovoltaic regions disposed overlying the surface area of the back cover member. In a preferred embodiment, the plurality of photovoltaic regions occupies a total photovoltaic spatial region. The device has an encapsulating material overlying a portion of the back cover member and has a front cover member coupled to the encapsulating material. An interface region is provided along at least a peripheral region of the back cover member and the front cover member. A sealed region is formed on at least the interface region to form an individual solar cell from the back cover member and the front cover member. In a preferred embodiment, the total photovoltaic spatial region/the surface area of the back cover is at a ratio of about 0.50 and less for the individual solar cell. Alternatively, other ratios such as 0.8 and less can exist depending upon the specific embodiment. Here, the terms “back cover member” and “front cover member” are provided for illustrative purposes, and not intended to limit the scope of the claims to a particular configuration relative to a spatial orientation according to a specific embodiment.

In a specific embodiment, the present invention provides an alternative solar cell device. The device has a first substrate member and a plurality of photovoltaic strips overlying the first substrate member. The device has an encapsulant material overlying a portion of the first substrate member. The device has a first refractive index characterizing the encapsulant material, and has a second substrate member comprising a plurality of optical concentrating elements thereon. In a preferred embodiment, the second substrate member is overlying the plurality of photovoltaic strips such that at least one of the optical concentrating elements is operably coupled to at least one of the one of the plurality of photovoltaic strips. Preferably, the plurality of concentrating elements is composed by at least a second substrate material. The device has a second refractive index characterizing the second substrate material. The second refractive index is substantially matched to the first refractive index to cause one or more photons to traverse through at least one of the optical concentrating elements through a portion of the encapsulant and to a portion of one of the photovoltaic strips to reduce an amount of internal reflection from a portion of the one concentrating element. In a specific embodiment, the reduced amount of internal reflection causes an increase of a quantity of photons reaching a photovoltaic region.

In yet an alternative embodiment, the present invention provides a solar cell device with improved encapsulant material. The device has a first substrate member and a plurality of photovoltaic strips overlying the first substrate member. The device has an encapsulant material overlying a portion of the first substrate member. The device has a first refractive index characterizing the encapsulant material, and has a second substrate member comprising a plurality of optical concentrating elements thereon. In a preferred embodiment, the second substrate member is overlying the plurality of photovoltaic strips such that at least one of the optical concentrating elements is operably coupled to at least one of the one of the plurality of photovoltaic strips. Preferably, the plurality of concentrating elements is composed by at least a second substrate material. The device has a second refractive index characterizing the second substrate material. The first refractive index of the encapsulant material is substantially matched with the second refractive index to facilitate a transfer of one or more photons from at least one of the optical concentrating elements to a portion of one of the photovoltaic strips in a preferred embodiment.

In yet an alternative embodiment, the present invention provides a packaged solar cell assembly being capable of stand-alone operation to generate power using the packaged solar cell assembly and/or with other solar cell assemblies. The packaged solar cell assembly includes rigid front cover member having a front cover surface area and a plurality of concentrating elements thereon. Each of the concentrating elements has a length extending from a first portion of the front cover surface area to a second portion of the front cover surface area. Each of the concentrating elements has a width provided between the first portion and the second portion. Each of the concentrating elements having a first edge region coupled to a first side of the width and a second edge region provided on a second side of the width. The first edge region and the second edge region extend from the first portion of the front cover surface area to a second portion of the front cover surface area. The plurality of concentrating elements is configured in a parallel manner extending from the first portion to the second portion. In addition, the packaged solar cell assembly includes a plurality of photovoltaic strips arranged respectively on the plurality of concentrating elements. Each of the plurality of photovoltaic strips has a strip width and a strip length. Each of the photovoltaic strips coupling at least one of the plurality of concentrating elements. The packaged solar cell assembly additionally includes a coupling material provided between each of the photovoltaic strips and each of the concentrating elements to optical couple the photovoltaic strip to the concentrating element. The packaged solar cell assembly further includes a rigid back cover member. The back cover member has a plurality of support regions. The plurality of support regions provides respectively mechanical support to respective plurality of photovoltaic strips. In addition, the package solar cell assembly includes a sealed region to mechanically couple the rigid back cover member to the rigid front cover member to provide a sealed sandwiched assembly capable of maintaining the plurality of photovoltaic strips substantially free from moisture. The sealed sandwiched assembly can be handled while maintaining the plurality of photovoltaic strips substantially free from mechanical damage.

In yet an alternative embodiment, the present invention provides a solar cell apparatus. The solar cell apparatus includes a backside substrate member comprising a backside surface region and an inner surface region. The solar cell apparatus also includes a plurality of photovoltaic strips spatially disposed in a parallel manner overlying the inner surface region. Each of the photovoltaic strips being characterized by a length and a width. The solar cell apparatus additionally includes a shaped concentrator device operably coupled to each of the plurality of photovoltaic strips. The shaped concentrator device has a first side and a second side. In addition, the solar cell apparatus includes an aperture region provided on the first side of the shaped concentrator device. Further, the solar cell apparatus includes an exit region provided on the second side of the shaped concentrator device. In addition, the solar cell apparatus includes a geometric concentration characteristic provided by a ratio of the aperture region to the exit region. The ratio can be characterized by a range from about 1.8 to about 4.5. The solar cell apparatus also includes a polymer material characterizing the shaped concentrator device. The solar cell apparatus additionally includes a refractive index of about 1.45 and greater characterizing the polymer material of the shaped concentrator device. Additionally, the solar cell apparatus includes a coupling material formed overlying each of the plurality of photovoltaic strips and coupling each of the plurality of photovoltaic regions to each of the concentrator devices. Moreover, the solar cell apparatus includes a refractive index of about 1.45 and greater characterizing the coupling material coupling each of the plurality of photovoltaic regions to each of the concentrator device.

In yet an alternative embodiment, the present invention provides a solar cell apparatus. The solar cell apparatus includes a backside substrate member, which includes a backside surface region and an inner surface region. The backside substrate member is characterized by a width. The solar cell apparatus also includes a plurality of photovoltaic strips spatially disposed in a parallel manner overlying the inner surface region. Each of the photovoltaic strips can be characterized by a length and a width. Addition, the solar cell apparatus includes a shaped concentrator device operably coupled to each of the plurality of photovoltaic strips. The shaped concentrator device has a first side and a second side. Moreover, the solar cell apparatus includes an aperture region provided on the first side of the shaped concentrator device. The solar cell apparatus also includes an exit region provided on the second side of the shaped concentrator device. The solar cell apparatus additionally includes a first reflective side provided between a first portion of the aperture region and a first portion of the exit region. Moreover, the solar cell apparatus includes a second reflective side provided between a second portion of the aperture region and a second portion of the exit region. In addition, the solar cell apparatus includes a geometric concentration characteristic provided by a ratio of the aperture region to the exit region. The ratio is characterized by a range from about 1.8 to about 4.5. Additionally, the solar cell apparatus includes a polymer material characterizing the shaped concentrator device, which includes the aperture region, exit region, first reflective side, and second reflective side. Furthermore, the solar cell apparatus has a refractive index of about 1.45 and greater characterizing the polymer material of the shaped concentrator device. Moreover, the solar cell apparatus includes a coupling material formed overlying each of the plurality of photovoltaic strips and coupling each of the plurality of photovoltaic regions to each of the concentrator devices. The solar cell apparatus additionally includes one or more pocket regions facing each of the first reflective side and the second reflective side. The one or more pocket regions can be characterized by a refractive index of about 1 to cause one or more photons from the aperture region to be reflected toward the exit region.

Many benefits are achieved by way of the present invention over conventional techniques. For example; the present technique provides an easy to use process that relies upon conventional technology such as silicon materials, although other materials can also be used. Additionally, the method provides a process that is compatible with conventional process technology without substantial modifications to conventional equipment and processes. Preferably, the invention provides for an improved solar cell, which is less costly and easy to handle. Such solar cell uses a plurality of photovoltaic regions, which are sealed within one or more substrate structures according to a preferred embodiment. In a preferred embodiment, the invention provides a method and completed solar cell structure using a plurality of photovoltaic strips free and clear from a module or panel assembly, which are provided during a later assembly process. Also in a preferred embodiment, one or more of the solar cells have less silicon per area (e.g., 80% or less, 50% or less) than conventional solar cells. In preferred embodiments, the present method and cell structures are also light weight and not detrimental to building structures and the like. That is, the weight is about the same or slightly more than conventional solar cells at a module level according to a specific embodiment. In a preferred embodiment, the present solar cell using the plurality of photovoltaic strips can be used as a “drop in” replacement of conventional solar cell structures. As a drop in replacement, the present solar cell can be used with conventional solar cell technologies for efficient implementation according to a preferred embodiment. Depending upon the embodiment, one or more of these benefits may be achieved. These and other benefits will be described in more detail throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified diagram illustrating an expanded view of a solar cell structure according to an embodiment of the present invention;

FIG. 2 is a simplified diagram of a back cover structure according to an embodiment of the present invention;

FIG. 2A is a detailed diagram of the back cover structure according to an embodiment of the present invention;

FIG. 3 is a simplified diagram illustrating a method of attaching a plurality of photovoltaic strips to the back cover structure according to an embodiment of the present invention;

FIG. 4 is a simplified diagram of an assembled back cover and photovoltaic strips according to an embodiment of the present invention;

FIG. 5 is a simplified diagram illustrating a method of providing an encapsulant overlying the assembled back cover and photovoltaic strips according to an embodiment of the present invention;

FIG. 6 is a simplified diagram of an assembled back cover, photovoltaic strips, and encapsulant according to an embodiment of the present invention;

FIG. 7 is a simplified diagram illustrating a method of assembling a front cover overlying the assembled back cover, photovoltaic strips, and encapsulant according to an embodiment of the present invention;

FIG. 8 is a more detailed diagram illustrating a plurality concentrating elements on a front cover according to an embodiment of the present invention;

FIG. 8A is a further detailed diagram illustrating the plurality of concentrating elements on the front cover according to an embodiment of the present invention;

FIG. 9 is a simplified diagram illustrating an assembled solar cell structure according to an embodiment of the present invention;

FIG. 9A is a more detailed diagram illustrating the assembled solar cell structure according to an embodiment of the present invention; and

FIG. 10 is a simplified diagram of a concentrator assembly according to an embodiment of the present invention

### DETAILED DESCRIPTION OF THE INVENTION

According to the present invention, techniques related to solar energy are provided. In particular, the present invention provides a method and resulting device fabricated from a plurality of photovoltaic regions provided within one or more substrate members. More particularly, the present invention provides a method and resulting device for manufacturing the photovoltaic regions within the substrate member, which is coupled to a plurality of concentrating elements. Merely by way of example, the invention has been applied to solar panels, commonly termed modules, but it would be recognized that the invention has a much broader range of applicability.

A method for fabricating a solar cell structure according to an embodiment of the present invention may be outlined as follows:

1. Provide a first substrate member;

2. Provide a plurality of photovoltaic strips overlying the first substrate member;

3. Provide an optical elastomer material overlying a portion of the first substrate (or alternatively a surface region of each of the photovoltaic strips or alternatively surface of the second substrate, which will be coupled to the plurality of photovoltaic strips);

4. Align a second substrate member comprising a plurality of optical concentrating elements thereon such that at least one of the optical concentrating elements being operably coupled to at least one of the one of the plurality of photovoltaic strips;

5. Couple the first substrate member to the second substrate member to form an interface region along a peripheral region of the first substrate member and the second substrate member;

6. Seal the interface region to form an individual solar cell from the first substrate and the second substrate;

7. Place solar cell in panel assembly; and

8. Perform other steps, as desired.

The above sequence of steps provides a method according to an embodiment of the present invention. As shown, the method uses a combination of steps including a way of forming a solar cell for a solar panel, which has a plurality of solar cells. Other alternatives can also be provided where steps are added, one or more steps are removed, or one or more steps are provided in a different sequence without departing from the scope of the claims herein. As an example, the plurality of photovoltaic strips are coupled to the second substrate and then the first substrate is provided and sealed to the second substrate. In a preferred embodiment, a coupling material is provided between the second substrate, which includes a plurality of concentrating elements, and the plurality of photovoltaic strips. Further details of the present method and resulting structures can be found throughout the present specification and more particularly below.

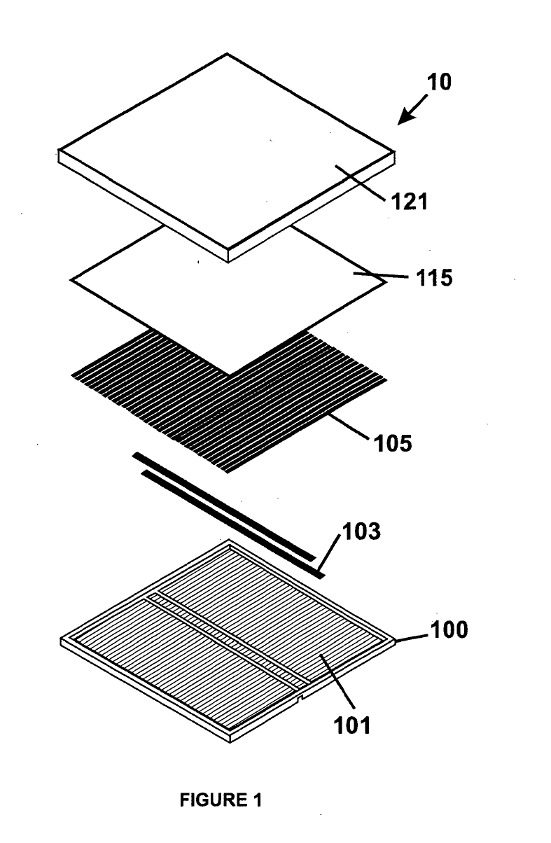

Referring now to FIG. 1, an expanded view 10 of a solar cell structure according to an embodiment of the present invention is illustrated. This diagram is merely an example, which should not unduly limit the scope of the claims herein. One of ordinary skill in the art would recognize many variations, modifications, and alternatives. As shown is an expanded view of the present solar cell device structure, which includes various elements. The device has a back cover member 101, which includes a surface area and a back area. The back cover member also has a plurality of sites, which are spatially disposed, for electrical members, such as bus bars, and a plurality of photovoltaic regions. Alternatively, the back cover can be free from any patterns and is merely provided for support and packaging. Of course, there can be other variations, modifications, and alternatives.

In a preferred embodiment, the device has a plurality of photovoltaic strips 105, each of which is disposed overlying the surface area of the back cover member. In a preferred embodiment, the plurality of photovoltaic strips correspond to a cumulative area occupying a total photovoltaic spatial region, which is active and converts sunlight into electrical energy.

An encapsulating material 115 is overlying a portion of the back cover member. That is, an encapsulating material forms overlying the plurality of strips, and exposed regions of the back cover, and electrical members. In a preferred embodiment, the encapsulating material can be a single layer, multiple layers, or portions of layers, depending upon the application. In alternative embodiments, as noted, the encapsulating material can be provided overlying a portion of the photovoltaic strips or a surface region of the front cover member, which would be coupled to the plurality of photovoltaic strips. Of course, there can be other variations, modifications, and alternatives.

In a specific embodiment, a front cover member 121 is coupled to the encapsulating material. That is, the front cover member is formed overlying the encapsulant to form a multilayered structure including at least the back cover, bus bars, plurality of photovoltaic strips, encapsulant, and front cover. In a preferred embodiment, the front cover includes one or more concentrating elements, which concentrate (e.g., intensify per unit area) sunlight onto the plurality of photovoltaic strips. That is, each of the concentrating elements can be associated respectively with each of or at least one of the photovoltaic strips.

Upon assembly of the back cover, bus bars, photovoltaic strips, encapsulant, and front cover, an interface region is provided along at least a peripheral region of the back cover member and the front cover member. The interface region may also be provided surrounding each of the strips or certain groups of the strips depending upon the embodiment. The device has a sealed region and is formed on at least the interface region to form an individual solar cell from the back cover member and the front cover member. The sealed region maintains the active regions, including photovoltaic strips, in a controlled environment free from external effects, such as weather, mechanical handling, environmental conditions, and other influences that may degrade the quality of the solar cell. Additionally, the sealed region and/or sealed member (e.g., two substrates) protect certain optical characteristics associated with the solar cell and also protects and maintains any of the electrical conductive members, such as bus bars, interconnects, and the like. Of course, there can be other benefits achieved using the sealed member structure according to other embodiments.

In a preferred embodiment, the total photovoltaic spatial region occupies a smaller spatial region than the surface area of the back cover. That is, the total photovoltaic spatial region uses less silicon than conventional solar cells for a given solar cell size. In a preferred embodiment, the total photovoltaic spatial region occupies about 80% and less of the surface area of the back cover for the individual solar cell. Depending upon the embodiment, the photovoltaic spatial region may also occupy about 70% and less or 60% and less or preferably 50% and less of the surface area of the back cover or given area of a solar cell. Of course, there can be other percentages that have not been expressly recited according to other embodiments. Here, the terms “back cover member” and “front cover member” are provided for illustrative purposes, and not intended to limit the scope of the claims to a particular configuration relative to a spatial orientation according to a specific embodiment. Further details of each of the various elements in the solar cell can be found throughout the present specification and more particularly below.

In a specific embodiment, the present invention provides a packaged solar cell assembly being capable of stand-alone operation to generate power using the packaged solar cell assembly and/or with other solar cell assemblies. The packaged solar cell assembly includes rigid front cover member having a front cover surface area and a plurality of concentrating elements thereon. Depending upon applications, the rigid front cover member consist of a variety of materials. For example, the rigid front cover is made of polymer material. As another example, the rigid front cover is made of transparent polymer material having a reflective index of about 1.4 or 1.42 or greater. According to an example, the rigid front cover has a Young's Modulus of a suitable range. Each of the concentrating elements has a length extending from a first portion of the front cover surface area to a second portion of the front cover surface area. Each of the concentrating elements has a width provided between the first portion and the second portion. Each of the concentrating elements having a first edge region coupled to a first side of the width and a second edge region provided on a second side of the width. The first edge region and the second edge region extend from the first portion of the front cover surface area to a second portion of the front cover surface area. The plurality of concentrating elements is configured in a parallel manner extending from the first portion to the second portion.

It is to be appreciated that embodiment can have many variations. For example, the embodiment may further includes a first electrode member that is coupled to a first region of each of the plurality of photovoltaic strips and a second electrode member coupled to a second region of each of the plurality of photovoltaic strips.

As another example, the solar cell assembly additionally includes a first electrode member coupled to a first region of each of the plurality of photovoltaic strips and a second electrode member coupled to a second region of each of the plurality of photovoltaic strips. The first electrode includes a first protruding portion extending from a first portion of the sandwiched assembly and the second electrode comprising a second protruding portion extending from a second portion of the sandwiched assembly.

In yet another specific embodiment, the present invention provides a solar cell apparatus. The solar cell apparatus includes a backside substrate member comprising a backside surface region and an inner surface region. Depending upon application, the backside substrate member can be made from various materials. For example, the backside member is characterized by a polymer material.

In yet another embodiment, the present invention provides a solar cell apparatus that includes a backside substrate member. The backside substrate member includes a backside surface region and an inner surface region. The backside substrate member is characterized by a width. For example, the backside substrate member is characterized by a length of about eight inches and less. As an example, the backside substrate member is characterized by a width of about 8 inches and less and a length of more than 8 inches.

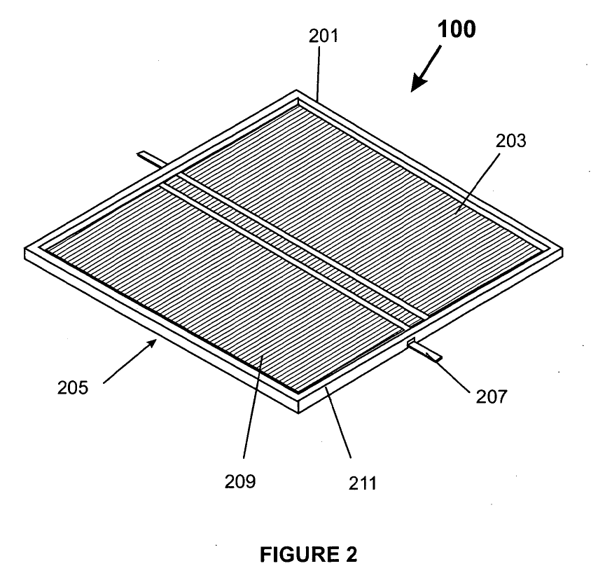

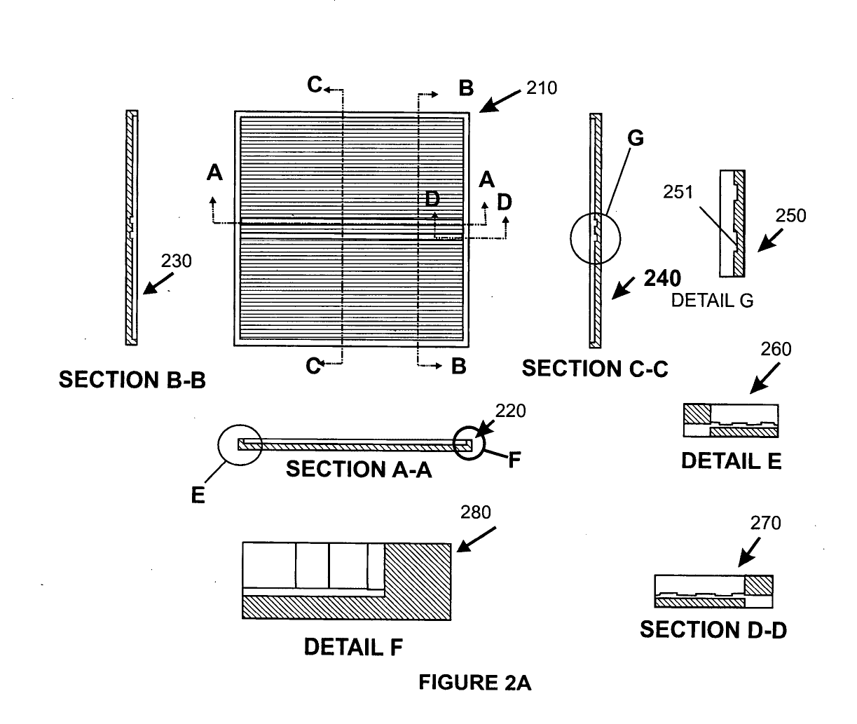

FIG. 2 is a simplified diagram of a back cover structure 100 according to an embodiment of the present invention. This diagram is merely an example, which should not unduly limit the scope of the claims herein. One of ordinary skill in the art would recognize many variations, modifications, and alternatives. As shown, the back cover has a bottom region 205 and a surface region 201, which includes a plurality of recessed regions 209. Each of the recessed regions corresponds to a spatial site for a photovoltaic material according to a specific embodiment. In a specific embodiment, the recessed region provides a mechanical and physical site for a photovoltaic strip or region of photovoltaic material. An area occupied by the recessed regions is surrounded by a peripheral region 203, which has an edge region 211 protruding slightly higher along a y-direction than the inner recessed regions according to a specific embodiment. Of course, there can be other variations, modifications, and alternatives.

Referring again to FIG. 2, the back cover also includes one or more conducting members, which are often bus bars 207. Each of the bus bars can couple a plurality of strips together in serial, parallel, or a combination of these configurations electrically. As shown, each of the bus bars is provided normal to a plurality of recessed regions. That is, each of the bus bars runs along an x-direction, while each of the recessed regions runs along a z-direction according to a specific embodiment. As will be appreciated, the bus bars are merely illustrative and not comprehensive. That is, there may be other bus bars (not shown) that run parallel to each of the recessed regions, or angular to each of the recessed regions, or any combination of these configurations. Further details of the conducting members can be found in the above Gibson Provisional Patent Application, commonly assigned, and hereby incorporated by reference herein. Of course, there can be other variations, modifications, and alternatives.

Depending upon the embodiment, the back cover can be made of a variety of suitable materials or combination of materials and layers. The back cover can be made using a polymer bearing material according to a specific embodiment. The polymer material may be a non-conductive material according to a preferred embodiment. Depending upon the application, the back cover can be a single layer or a multilayered material, and is preferably not optically transparent, but may also be optically transparent according to other embodiments. In a preferred embodiment, the back cover uses a polymer material that has been molded or machined to form the plurality of recessed regions and other desired characteristics. Of course, there can be other variations, modifications, and alternatives.

For example, the rigid back cover member can be made of a variety Of materials. For example, the back front cover is made of polymer material, a glass, or other suitable material. According to an example, the rigid back cover has a suitable Young's Modulus. The plurality of support regions provides respectively mechanical support to respective plurality of photovoltaic strips. In addition, the package solar cell assembly includes a sealed region to mechanically couple the rigid back cover member to the rigid front cover member to provide a sealed sandwiched assembly capable of maintaining the plurality of photovoltaic strips substantially free from moisture. For example, the moisture is less than a predetermined amount in parts per million to prevent corrosion and facilitate operation of the solar cell device. The sealed sandwiched assembly can be handled while maintaining the plurality of photovoltaic strips substantially free from mechanical damage. As merely an example, mechanical damage is breakage of one or more of the photovoltaic strips.

A detailed view of the back cover is provided in reference to FIG. 2A. As shown, a top-view 210 of the back cover is illustrated. Alternative views are also provided. For example, a cross-section “A-A” 220 is illustrated. Such A-A cross section is along a region for a bus bar member according to a specific embodiment. Detail “F” 280 and detail “E” 260 are also illustrated. Detail F corresponds to a peripheral or edge region of the back cover. Similarly, detail F corresponds to an alternative peripheral or edge region of the back cover. Cross sections “B-B” and “C-C” 230, 240 are also illustrated. Such cross-sections B-B and C-C relate to respective recessed region lengths along the back cover. Details of “G” 250 in section C-C are also illustrated. Each of the recessed regions 251 correspond to a site for a bus bar member according to a specific embodiment. An alternative section “D-D” 270 of the top-view 210 has also been illustrated for the back cover. Of course, there can be other variations, modifications, and alternatives. Further details of the present method and structures can be found throughout the present specification and more particularly below.

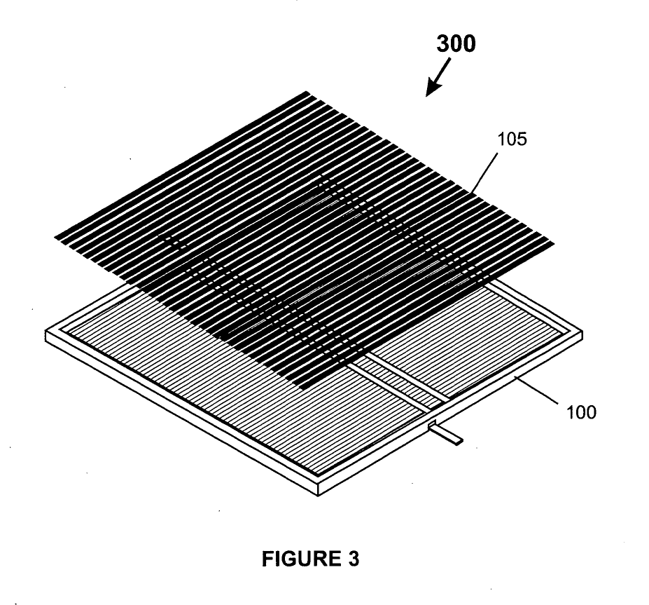

FIG. 3 is a simplified diagram 300 illustrating a method of attaching a plurality of photovoltaic strips 105 to the back cover structure 100 according to an embodiment of the present invention. This diagram is merely an example, which should not unduly limit the scope of the claims herein. One of ordinary skill in the art would recognize many variations, modifications, and alternatives. As shown, the photovoltaic strips are each aligned to a respective recessed region. Each of the photovoltaic strips has a predetermined width, length, and depth to allow it to fit within a portion of the recessed region or other physical site depending upon the embodiment.

In a specific embodiment, each of the photovoltaic strips is made of a silicon bearing material, which includes a photo energy conversion device therein. That is, each of the strips is made of single crystal and/or poly crystalline silicon that have suitable characteristics to cause it to convert applied sunlight or electromagnetic radiation into electric current energy according to a specific embodiment. An example of such a strip is called the Sliver Cell® product manufactured by Origin Energy of Australia, but can be others. In an alternative preferred embodiment, the strip can be provided from a conventional solar cell. That is, the strip can be provided by dicing (e.g., saw, scribe and break) a conventional solar cell or suitably designed solar cell according to a specific embodiment. Depending upon the embodiment, the conventional solar cell can be a back contact cell manufactured by SunPower Corp. located at 3939 North First Street, San Jose, Calif. 95134 or other solar cell types such as those manufactured by BP Solar International Inc., Shell Solar, headquartered in The Hague, The Netherlands, Q-Cells AG of Germany, SolarWorld AG, Kurt-Schumacher-Str. 12-14, 53113 Bonn/Germany, Sharp Corporation, Osaka, Japan, Kyocera Solar Inc., and others. In other examples, the strips or regions of photovoltaic material can be made of other suitable materials such as other semiconductor materials, including semiconductor elements listed in the Periodic Table of Elements, polymeric materials that have photovoltaic properties, or any combination of these, and the like. Of course, there can be other variations, modifications, and alternatives.

In a specific embodiment, a packaged solar cell assembly includes a plurality of photovoltaic strips arranged respectively on the plurality of concentrating elements. Each of the plurality of photovoltaic strips has a strip width and a strip length. Each of the photovoltaic strips coupling at least one of the plurality of concentrating elements. The packaged solar cell assembly additionally includes a coupling material provided between each of the photovoltaic strips and each of the concentrating elements to optical couple the photovoltaic strip to the concentrating element.

In another specific embodiment, the solar cell apparatus also includes a plurality of photovoltaic strips spatially disposed in a parallel manner overlying the inner surface region. Each of the photovoltaic strips being characterized by a length and a width. As merely an example, each of the photovoltaic strips includes a plurality of p-type regions and a plurality of n-type regions. Each of the p-type regions is coupled to at least one of the n-type region. As an example, the photovoltaic strips are made of silicon material.

As an example, the solar cell apparatus includes a plurality of photovoltaic strips spatially disposed in a parallel manner overlying the inner surface region. Each of the photovoltaic strips can be characterized by a length and a width. Addition, the solar cell apparatus includes a shaped concentrator device operably coupled to each of the plurality of photovoltaic strips. The shaped concentrator device has a first side and a second side. Moreover, the solar cell apparatus includes an aperture region provided on the first side of the shaped concentrator device. The solar cell apparatus also includes an exit region provided on the second side of the shaped concentrator device.

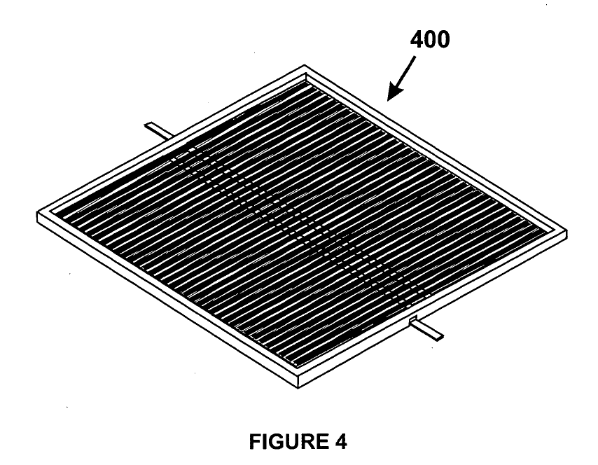

FIG. 4 is a simplified diagram 400 of an assembled back cover and photovoltaic strips according to an embodiment of the present invention. This diagram is merely an example, which should not unduly limit the scope of the claims herein. One of ordinary skill in the art would recognize many variations, modifications, and alternatives. As shown, each of the photovoltaic strips has been provided in a respective recessed region or site on the back cover. Each of the strips is preferably mechanically secure onto the recessed region in a specific embodiment. A first group of strips may be coupled to at least one of the bus bars and a second group of strips may be coupled to another group of bus bars. Each of the strips is coupled to at least two of the bus bars or like conduction members to provide an electrical circuit for providing electrical power. Alternatively, the back cover can be provided onto an assembled front cover and photovoltaic strip structure according to an alternative embodiment of the present invention. Of course, there can be other variations, modifications, and alternatives.

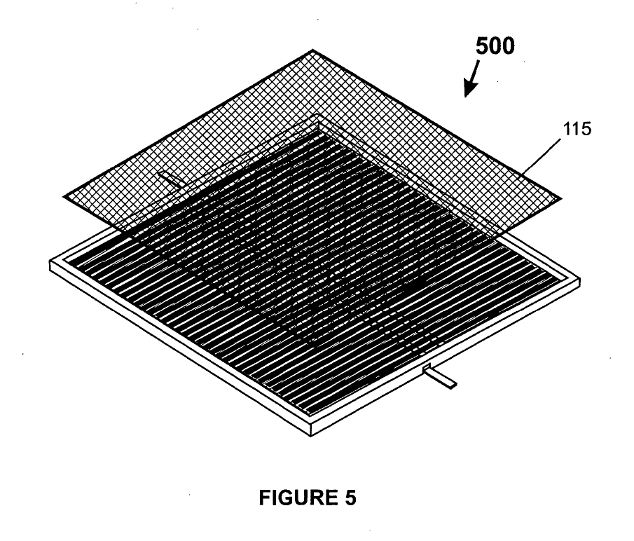

FIG. 5 is a simplified diagram 500 illustrating a method of providing an encapsulant 115 overlying the assembled back cover and photovoltaic strips according to an embodiment of the present invention. This diagram is merely an example, which should not unduly limit the scope of the claims herein. One of ordinary skill in the art would recognize many variations, modifications, and alternatives. As shown, the encapsulant can be a single layer 115 or multiple layers according to a specific embodiment. The encapsulant may also be provided in liquid form, which is cured to enclose and seal each of the photovoltaic strips and portions of the bus bar members in a specific embodiment.

Depending upon the embodiment, the encapsulant is made of a suitable material for desired optical, electrical, and physical characteristics. The optical is preferably an optical elastomer material, which begins as a liquid and cures to form a solid material. The elastomer material has suitable thermal and optical characteristics. That is, a refractive index of the elastomer material is substantially matched to a overlying front cover according to a specific embodiment. In a specific embodiment, the encapsulant material adapts for a first coefficient of thermal expansion of the plurality of photovoltaic strips on the first substrate member and a second coefficient of thermal expansion associated with the second substrate. In a specific embodiment, the encapsulant material facilitates transfer of one of more photons between one of the concentrating elements and one of the plurality of photovoltaic strips. The encapsulant material can act as a barrier material, an electrical isolating structure, a glue layer, and other desirable features. As an example, the term “elastomer” should be given its broadest interpretation according to one of ordinary skill in the art. Of course, there can be other variations, modifications, and alternatives.

According to an embodiment, the sealed sandwiched assembly is capable of being handled while maintaining the plurality of photovoltaic strips substantially free from mechanical damage. For example, the sealed region includes ultrasonic (e.g., 15 to 30 kilo-Hertz) welded portion. As another example, the sealed region is provided by a vibrational welded portion, a thermal formed portion, a chemical formed portion, a glued portion, an adhered portion, or an irradiated portion, e.g., laser. According to an embodiment, the sealed sandwiched assembly has a total thickness of 7 millimeters or less. In a specific embodiment, the sealed sandwiched assembly has a width ranging from about 100 millimeters to about 210 millimeters and a length ranging from about 100 millimeters to about 210 millimeters. In a specific embodiment, the sealed sandwiched assembly can even have a length of about 300 millimeters and greater. Of course, there can be other variations, modifications, and alternatives.

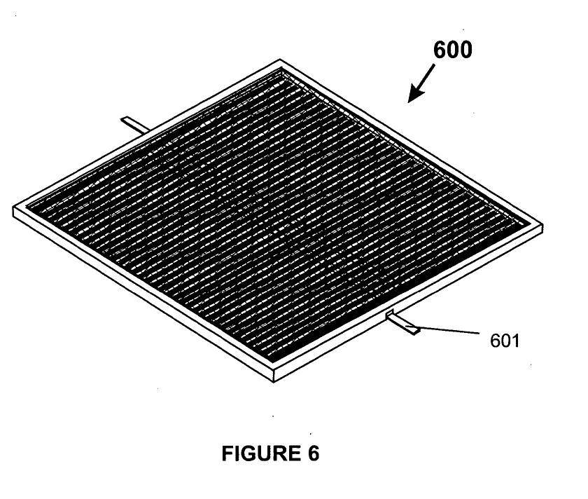

FIG. 6 is a simplified diagram 600 of an assembled back cover, photovoltaic strips, and encapsulant according to an embodiment of the present invention. This diagram is merely an example, which should not unduly limit the scope of the claims herein. One of ordinary skill in the art would recognize many variations, modifications, and alternatives. As shown, the encapsulant has been formed overlying surfaces of the photovoltaic strips provided in the recessed regions and portions of the bus bar members. Other portions 601 of the bus bar member protrude from the periphery of the back cover member, which now includes the photovoltaic strips and encapsulant according to a specific embodiment. Further details of the present method and structure are provided throughout the present specification and more particularly below.

As an example, the photovoltaic strips are arranged respectively on a plurality of optical concentrating elements. Each of the plurality of photovoltaic strips has a strip width and a strip length. Each of the photovoltaic strips is coupling at least one of the plurality of concentrating elements. For example, each of the photovoltaic strips converts light directly into electrical current. As another example, each of the photovoltaic strips is made of a material selected from mono-crystalline silicon, poly-crystalline silicon, amorphous silicon copper indium diselenide (CIS), cadmium telluride CdTe, or nanostructured materials. Of course, there can be other variations, modifications, and alternatives.

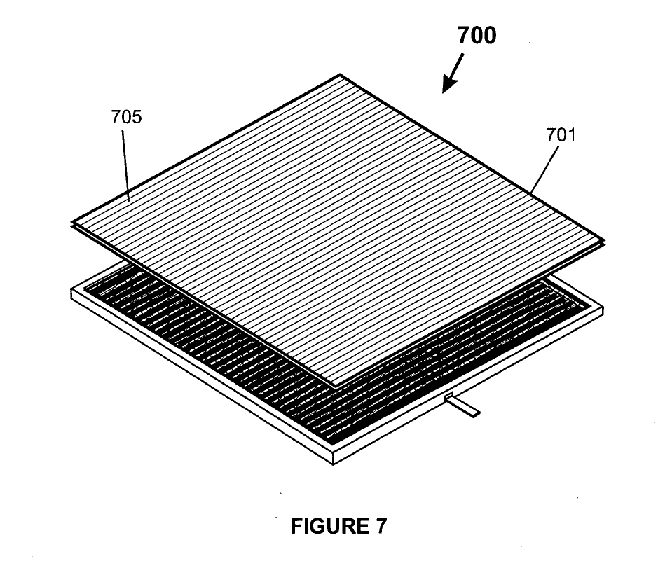

FIG. 7 is a simplified diagram 700 illustrating a method of assembling a front cover overlying the assembled back cover, photovoltaic strips, and encapsulant according to an embodiment of the present invention. This diagram is merely an example, which should not unduly limit the scope of the claims herein. One of ordinary skill in the art would recognize many variations, modifications, and alternatives. As shown, the front cover 701 is aligned to the partially assembled back cover and strips according to a specific embodiment. In a preferred embodiment, the front cover includes a plurality of concentrating elements 705, which are spatially disposed in parallel to each of the recessed regions and each of the strips. Each of the concentrating elements includes a length disposed along a z-direction according to a specific embodiment. Further details of the front cover including concentrating elements are provided throughout the present specification and more particularly below.

Depending upon application, the front cover member may be implemented in various ways. For example, the rigid front cover member material can be made of polymer material, glass material, multilayered material, etc. According to an embodiment, the rigid front cover member is a molded member provided by injection, transfer, compression, or extrusion. For example, the rigid front cover member is characterized by an index of refraction of 1.4 or greater. According to an embodiment, the rigid front cover member is optically transparent. For example, the rigid front cover member is provided by a light-transmission material 88% or greater. As another example, the rigid front cover member has light absorption of 4% or less. Of course, there can be other variations, modifications, and alternatives.

In a specific embodiment, a cell assembly includes an optical coupling material provided between each of the photovoltaic strips and each of the concentrating elements to optical couple the photovoltaic strip to the concentrating element. For example, the optical coupling material is a liquid (as a starting material), an adhesive, a fluid (e.g., solid, liquid), a film or one or more films, which can be spun on, deposited, coated, evaporated, sprayed, painted, or provided through other suitable techniques. As another example, the optical coupling material is characterized by a light transmission of about 88% or greater or 92% or greater; an index of refraction of 1.42 or greater, and a UV stabilizer. According to an embodiment, the optical coupling material has a suitable index of elasticity, which allows for mechanical and/or thermal variations among the substrates and photovoltaic strips. Of course, there can be other variations, modifications, and alternatives.

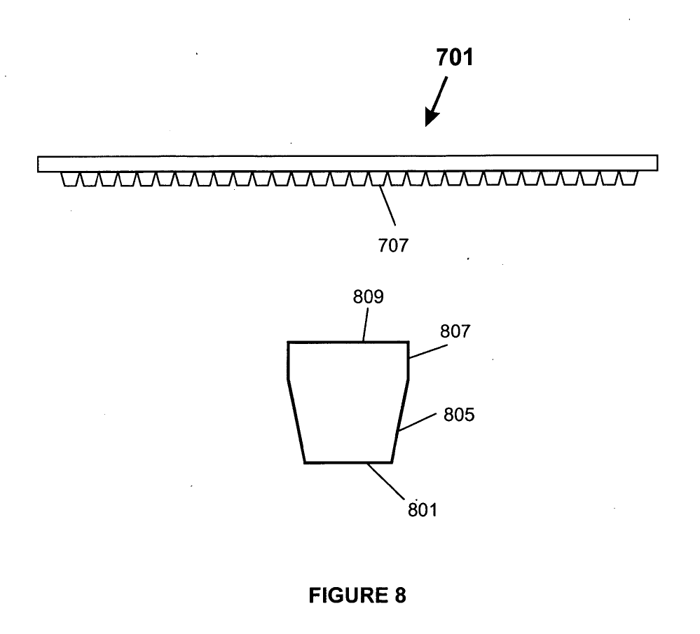

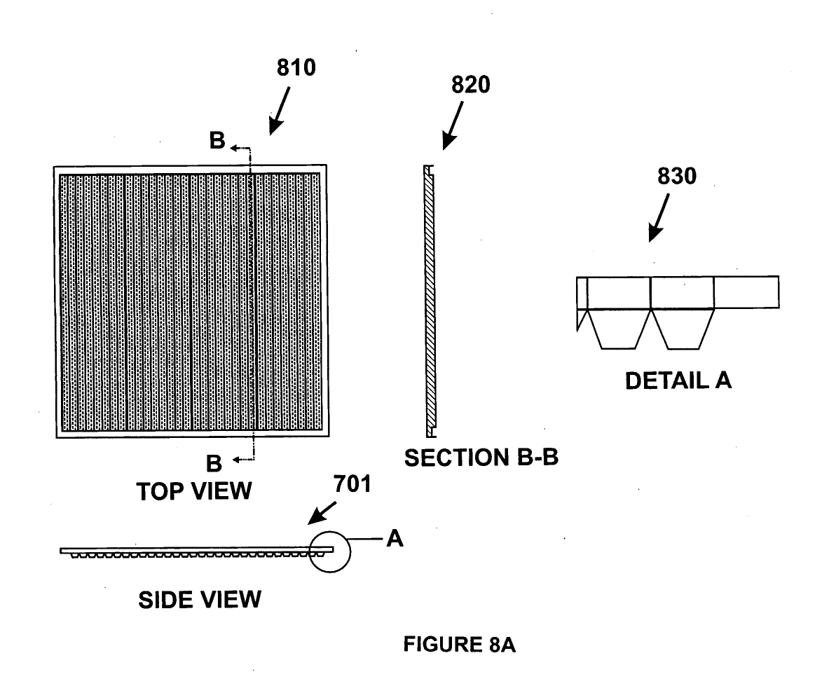

FIG. 8 is a more detailed diagram illustrating a plurality of concentrating elements on a front cover 701 according to an embodiment of the present invention. This diagram is merely an example, which should not unduly limit the scope of the claims herein. One of ordinary skill in the art would recognize many variations, modifications, and alternatives. As shown, each of the concentrating elements for the strip configuration includes a trapezoidal shaped member. Each of the trapezoidal shaped members has a bottom surface coupled to a pyramidal shaped region coupled to an upper region. The upper region is defined by surface 809, which is co-extensive of the front cover. Each of the members is spatially disposed and in parallel to each other according to a specific embodiment. Here, the term “trapezoidal” or “pyramidal” may include embodiments with straight or curved or a combination of straight and curved walls according to embodiments of the present invention. Depending upon the embodiment, the concentrating elements may be on the front cover, integrated into the front cover, and/or be coupled to the front cover according to embodiments of the present invention. Further details of the front cover with concentrating elements is provided more particularly below.

In a specific embodiment, a solar cell apparatus includes a shaped concentrator device operably coupled to each of the plurality of photovoltaic strips. The shaped concentrator device has a first side and a second side. In addition, the solar cell apparatus includes an aperture region provided on the first side of the shaped concentrator device. As merely an example, the concentrator device includes a first side region and a second side region. Depending upon application, the first side region is characterized by a roughness of about 100 nanometers or 120 nanometers RMS and less, and the second side region is characterized by a roughness of about 100 nanometers or 120 nanometers RMS and less. For example, the roughness is characterized by a dimension value of about 10% of a light wavelength derived from the aperture regions. Depending upon applications, the backside member can have a pyramid-type shape.

As an example, the solar cell apparatus includes an exit region provided on the second side of the shaped concentrator device. In addition, the solar cell apparatus includes a geometric concentration characteristic provided by a ratio of the aperture region to the exit region. The ratio can be characterized by a range from about 1.8 to about 4.5. The solar cell apparatus also includes a polymer material characterizing the shaped concentrator device. The solar cell apparatus additionally includes a refractive index of about 1.45 and greater characterizing the polymer material of the shaped concentrator device. Additionally, the solar cell apparatus includes a coupling material formed overlying each of the plurality of photovoltaic strips and coupling each of the plurality of photovoltaic regions to each of the concentrator devices. For example, the coupling material is characterized by a suitable Young's Modulus.

As merely an example, the solar cell apparatus includes a refractive index of about 1.45 and greater characterizing the coupling material coupling each of the plurality of photovoltaic regions to each of the concentrator device. Depending upon application, the polymer material is characterized by a thermal expansion constant that is suitable to withstand changes due to thermal expansion of elements of the solar cell apparatus.

For certain applications, the plurality of concentrating elements has a light entrance area (A1) and a light exit area (A2) such that A2/A1 is 0.8 and less. As merely an example, the plurality of concentrating elements has a light entrance area (A1) and a light exit area (A2) such that A2/A1 is 0.8 and less, and the plurality of photovoltaic strips are coupled against the light exit area. In a preferred embodiment, the ratio of A2/A1 is about 0.5 and less. For example, each of the concentrating elements has a height of 7 mm or less. In a specific embodiment, the sealed sandwiched assembly has a width ranging from about 100 millimeters to about 210 millimeters and a length ranging from about 100 millimeters to about 210 millimeters. In a specific embodiment, the sealed sandwiched assembly can even have a length of about 300 millimeters and greater. As another example, each of the concentrating elements has a pair of sides. In a specific embodiment, each of the sides has a surface finish of 100 nanometers or less or 120 nanometers and less RMS. Of course, there can be other variations, modifications, and alternatives.

Referring now to FIG. 8A, the front cover has been illustrated using a side view 701, which is similar to FIG. 8. The front cover also has a top-view illustration 801. A section view 820 from “B-B” has also been illustrated. A detailed view “A” of at least two of the concentrating elements 830 is also shown. Depending upon the embodiment, there can be other variations, modifications, and alternatives.

Depending upon the embodiment, the concentrating elements are made of a suitable material. The concentrating elements can be made of a polymer, glass, or other optically transparent materials, including any combination of these, and the like. The suitable material is preferably environmentally stable and can withstand environmental temperatures, weather, and other “outdoor” conditions. The concentrating elements can also include portions that are coated with an anti-reflective coating for improved efficiency. Coatings can also be used for improving a durability of the concentrating elements. Of course, there can be other variations, modifications, and alternatives.

In a specific embodiment, the solar cell apparatus includes a first reflective side provided between a first portion of the aperture region and a first portion of the exit region. As merely an example, the first reflective side includes a first polished surface of a portion of the polymer material. For certain applications, the first reflective side is characterized by a surface roughness of about 120 nanometers RMS and less.

Moreover, the solar cell apparatus includes a second reflective side provided between a second portion of the aperture region and a second portion of the exit region. For example, the second reflective side comprises a second polished surface of a portion of the polymer material. For certain applications, the second reflective side is characterized by a surface roughness of about 120 nanometers and less. As an example, the first reflective side and the second reflective side provide for total internal reflection of one or more photons provided from the aperture region.

In addition, the solar cell apparatus includes a geometric concentration characteristic provided by a ratio of the aperture region to the exit region. The ratio is characterized by a range from about 1.8 to about 4.5. Additionally, the solar cell apparatus includes a polymer material characterizing the shaped concentrator device, which includes the aperture region, exit region, first reflective side, and second reflective side. As an example, the polymer material is capable of being free from damaged caused by ultraviolet radiation.

Furthermore, the solar cell apparatus has a refractive index of about 1.45 and greater characterizing the polymer material of the shaped concentrator device. Moreover, the solar cell apparatus includes a coupling material formed overlying each of the plurality of photovoltaic strips and coupling each of the plurality of photovoltaic regions to each of the concentrator devices. The solar cell apparatus additionally includes one or more pocket regions facing each of the first reflective side and the second reflective side. The one or more pocket regions can be characterized by a refractive index of about 1 to cause one or more photons from the aperture region to be reflected toward the exit region.

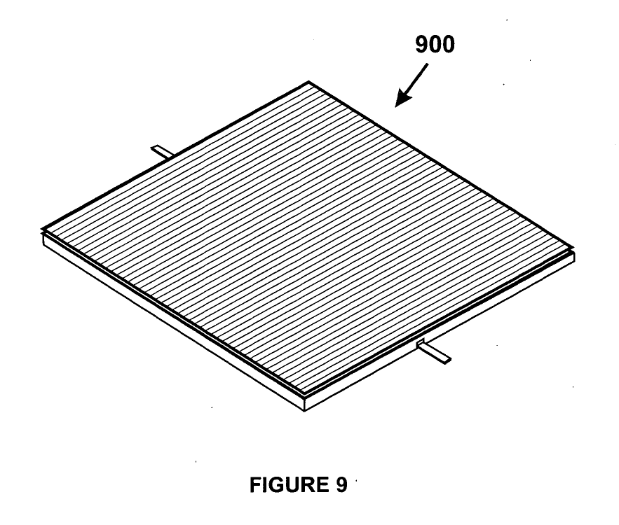

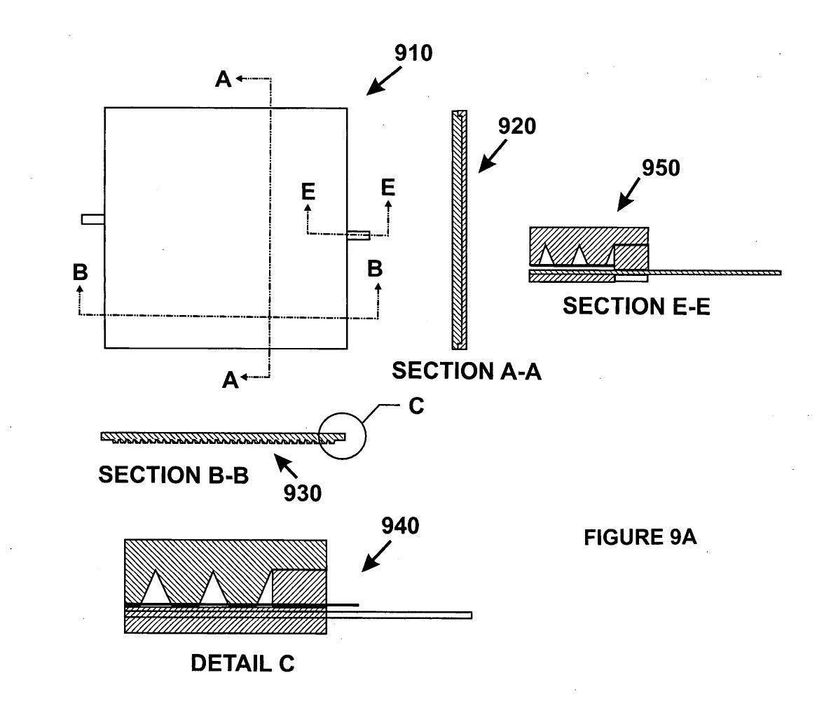

FIG. 9 is a simplified diagram illustrating an assembled solar cell structure 900 according to an embodiment of the present invention. As shown, the cell structure includes the back cover, plurality of strips, encapsulant, front cover, including concentrator elements, and other features according to a specific embodiment. Portions of bus bars are also exposed for electrical connection to other cells or peripheral circuitry in the solar cell panel or module according to the present invention. Further details of the present solar cell structure can be found throughout the present specification and more particularly below.

Referring now to FIG. 9A, various views illustrating the assembled cell structure are provided. As shown, the assembled views include a top-view illustration 910, which has various cross-sections including at least “A-A” “B-”B″ and “E-E.” The details of A-A 920 are illustrated and run along lengths of the photovoltaic strips. The details of B-B 930 are also illustrated and run normal to the lengths of the photovoltaic strips. An edge portion “C” 940 of the B-B″ details is also shown. The edge portion illustrates a recessed region, a photovoltaic strip, encapsulant, and concentrator element corresponding to the photovoltaic strips, among other features. A detail “E-E” 950 along an edge region parallel to one of the bus members is also shown. Of course, there can be other variations, modifications, and alternatives.

In a preferred embodiment, the present method and resulting device has the back cover coupled to the front cover to form an interface region along a peripheral region or other suitable regions, which contain one or more of the photovoltaic regions composed of photovoltaic materials. In other embodiments, coupling occurs using the encapsulant material or other like material or combinations of these elements. The method seals the interface region to form an individual solar cell from the first substrate and the second substrate and places the solar cell in panel assembly. Depending upon the embodiment, sealing the covers together occurs using a variety of suitable techniques such as ultrasonic welding, vibrational welding, thermal processes, chemical processes, a glue material, an irradiation process (e.g., laser, heat lamp), any combination of these, and others. In a specific embodiment, the sealing technique uses a laser light source called LAM 200 and 300 manufactured by Branson Ultrasonics Corporation, but can be others. Of course, there can be other variations, modifications and alternatives. Further details of the present method and structure can be found throughout the present specification and more particularly below.

### Examples

To prove the operation of the present methods and structures, certain details of the methods and structures in examples are provided. These examples are merely illustrations and should not unduly limit the scope of the claims herein. One of ordinary skill in the art would recognize many variations, alternatives, and modifications. These examples should also be read in reference to the other descriptions provided herein for clarification purposes. Details of these examples can be found below.

In general, the design and efficiency of the present solar cell method and structure occurs using combinations of elements and structures. As an example, the present concentrator is bound to the photovoltaic material characteristics according to a specific embodiment. Our present concentrator has achieved a low concentration ratio (e.g., 2 times, 3 times, 4 times) to reduce cost associated with the complexity of high concentrating systems. In a preferred embodiment, the low concentration ratio is about 3 times and less for the present concentrating elements for non-tracking solar panel embodiments. The present methods and systems also allow for a non-tracking capability, which leads to reducing cost and increasing reliability according to a specific embodiment. To make the concentrator efficient for low cost manufacturing, the desirable concentrator contains a low volume of polymers. Low volume is achieved by making the concentrator dimensions as small as possible according to a preferred embodiment to allow for a photovoltaic strip of a determined shape and size that is smaller than conventional photocell structures. The volume of the concentrator is also low to make it lightweight, easy to manufacture, reduce material costs, and allow for handling by human users and/or automation according to a specific embodiment. As merely an example, concentration designs and methods are provided throughout the present specification and more particularly below. That is, one or more of the features below can be incorporated in the present solar cell methods and devices according to embodiments of the present invention.

1. Trough design to improve and/or maximize the efficiency of the concentrator;

2. Trough design for non-tracking system to be oriented east to west;

3. Utilize total internal reflection (TIR) to maximize efficiency;

4. A concentrator made of a solid material with a high index of refraction for desired TIR;

5. The higher the index of refraction, the better the concentrator collects diffuse and off-angle light;

6. Optical concentration ratio is a function of the aperture relative to the exit;

7. Effective concentration is always less than the optical concentration due to system losses (The ratio of the optical to the effective concentration is the efficiency of the concentrator);

8. The concentrator can be made of either glass or polymers;

9. The concentrator material must transmit as much light as possible to the photovoltaic material;

10. Higher Index of Refraction material is preferred;

11. Suggested higher index of refraction material products can be, but not limited to: (1) Topas™ product manufactured by Ticona polymers; (2) Cleartuf™ product manufactured by M&G polymers (3) Lexan™ product manufactured by GE Advanced Materials; (4) Makrolon™ product manufactured by Bayer Materials Science; (5) Calibre™ product manufactured by Dow Chemical; and (6) Tefzel™ manufactured by DuPont, (7) acrylic material, (8) Plexiglas® acrylic resin color technology Altuglas International, Highland, Mich., but can be others.

Depending upon the embodiment, one or more of these features can be used. Of course, there can be other variations, modifications, and alternatives. Additional details of the present method and structures are provided below.

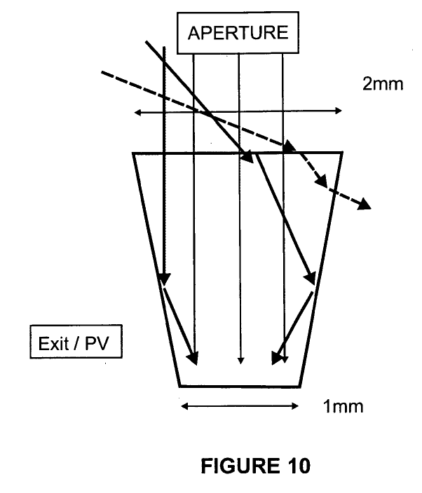

In a specific embodiment, a method for concentrating light has been described briefly below for a 2× concentrator cross section in reference to FIG. 10, which illustrates a concentrator method and structure.

1. Light that enters directly above the exit perpendicular to the aperture surface will strike the photovoltaic material directly without a substantial reflection. This is shown by the black rays.

2. Light that enters to the side of the exit but perpendicular to the aperture surface will strike the side of the concentrator and reflect towards the photovoltaic material with one or more reflections. This is shown by the red ray.

3. Light that enters the concentrator at an angle to the aperture surface will first bend. The amount of bending will be a function of the index of refraction of the concentrator material and the index of refraction of the material outside the concentrator. Then the light will strike the side of the concentrator and if the angle of incidence is less than the critical angle the light will reflect towards the photovoltaic material with one or more reflections. This is shown by the green ray.

4. Light that enters the concentrator at an angle to the aperture surface will first bend. The amount of bending will be a function of the index of refraction of the concentrator material and the index of refraction of the material outside the concentrator. Then the light will strike the side of the concentrator and if the angle of incidence is greater than the critical angle the light exits the concentrator. This is shown by the orange ray.

As shown above, the present method achieves certain benefits using the present concentrator structure and methods for the solar cell. Depending upon the embodiment, other features have been incorporated. That is, in a specific embodiment, the following should be true to achieve a total internal reflection condition:

1. The refractive material has a higher indexer of refraction that the incident material, which is on the outside.

Air and a vacuum typically has an index of refraction of around one (1).

Optical polymers and glass concentrators typically have index of refractions of about one and one half (e.g., 1.48, 1.49, 1.5) or greater.

2. The light ray strikes the surface at less than the critical angle.

3. A TIR surface has a very smooth surface finish and remains free of all contaminants such as dust, moisture, finger prints etc.

From Snell's law, the critical angle is defined as follows.

θcrit=sin e⁻¹(nᵣ/nᵢ)=inv−sin e(nᵣ/nᵢ)

where nᵣ is the index of refraction of the'refractive material; and

nᵢ is the index of refraction of the incident material.

Certain simulations have been performed to define shapes of the side walls and the depth of the concentrator according to the present example. The present illustration shows straight walls according to a specific embodiment. However, efficiency can be improved by making curved walls and/or a combination of straight and curved walls according to other embodiments. An improved or even optimal depth and side wall shape depends on the concentration ratio according to the present example.

As a desirable design strategy, the present solar cell and methods should emulate a conventional mono-crystalline silicon based cell as closely as possible. That is, such conventional cells can be those manufactured by SunPower Corp. located at 3939 North First Street, San Jose, Calif. 95134 or other solar cell types such as those manufactured by BP Solar International Inc., Shell Solar, headquartered in The Hague, The Netherlands, Q-Cells AG of Germany, SolarWorld AG, Kurt-Schumacher-Str. 12-14, 53113 Bonn/Germany, Sharp Corporation, Osaka, Japan, Kyocera Solar Inc., and others. Alternatively, the solar cells and/or strips can be manufactured using thin film and/or nanotechnology processes. As an example, such thin film processes, e.g., copper indium diselenide (CIS), cadmium telluride (CdTe), or other suitable materials, including combinations, and the like. Depending upon the embodiment, the present solar cell and method has a form, fit, and function that matches certain features of conventional photovoltaic cells. In this example, the cell form should be square, as thin as possible (e.g., less than 3 millimeters, less than 7 millimeters), and as light as possible, and have other desirable features. Of course, there can be other variations, modifications, and alternatives.

As an example, conventional cells are 125 mm² and 150 mm². We believe that it is likely that larger cells sizes may be used in the future up to 300 mm². However, for some smaller module applications, smaller cells might be desirable. High voltage, low power modules for battery charging could be one example. 50 min² cells may be desirable for this application. Of course, there can be other variations, modifications, and alternatives.

The thickness of the concentrator is a function of the width of the photovoltaic material cell. Narrower cells allow for small exit sizes, smaller apertures, and narrower concentrators. However, narrower photovoltaic cells often require more cells and handling operations to fill a certain area with cells, which may increase costs. For certain applications it is possible that a very narrow cell is required. In this embodiment, the photovoltaic width could be 0.5 mm wide and less depending upon the embodiment. For other applications, width might not be an issue however the cost can be reduced by fewer handling operations. In this case it is possible that a width up to 3 mm is desirable. Depending upon the embodiment, the cell uses various photovoltaic strips.

In a specific embodiment, the present invention provides a solar cell using a plurality of photovoltaic strips or regions. To support the form, fit, and function of the present solar cell the photovoltaic strips has one or more of the following characteristics:

1. Physical Dimensions (of photovoltaic strips)
Width of 0.5 mm to 3.0 mm with 1 mm preferred
Length of 50 mm to 150 mm with 125 mm preferred (or 210 or 300 mm)
Thickness of 20 to 100 microns (or Thickness of 50 to 400 microns)

2. Positive and Negative Electrical Contacts

3. Anti-reflective coating

4. Made of mono-crystalline PV silicon or polycrystalline PV silicon or silicon germanium alloys and the like

5. Efficiency of 15% or greater at standard test conditions (STC)

6. Open Circuit Voltage between 0.6V and 0.7V (STC)

STC: irradiance level 1000 W/m², spectrum AM 1.5 and cell temperature 25° C. Of course, there can be other variations, modifications, and alternatives.

It is to be appreciated that the present invention provides various advantages for solar cells. For example, the present invention provides a cost-effective and energy efficient solution for solar cell systems. There are other benefits as well. As an example, the present method and structure provide for packaging of a plurality of photovoltaic strips coupled to respectively plurality of concentrating elements to increase an efficiency of the photovoltaic strips while using less photovoltaic material. The packaged assembly is stand alone and can withstand external forces and/or other environmental conditions according to preferred embodiments. The package is easy to handle and can be used alone or with other packaged cells in a large module, which can string each of the cells in serial and/or parallel configuration according to a specific embodiment. In a specific embodiment, the present package configuration can be changed and designed using selected shapes and sizes, which allow for custom or specialized applications. In a preferred embodiment, the present method and structure (including cell and module) uses less material and may be easier to manufacture than conventional solar cell processes. In certain embodiments, the present invention offers a relative fficiency of about 80% and greater as compared to an original cell in a module. Depending upon the embodiment, one or more of these benefits can be achieved.

It is also understood that the examples and embodiments described herein are for illustrative purposes only and that various modifications or changes in light thereof will be suggested to persons skilled in the art and are to be included within the spirit and purview of this application and scope of the appended claims.

What is claimed is:

1. A method for fabricating a solar cell free and separate from a solar panel, the method comprising:
providing a first substrate member comprising a plurality of photovoltaic strips thereon;
providing an optical elastomer material overlying a portion of the first substrate member;
aligning a second substrate member comprising a plurality of optical concentrating elements thereon such that at least one of the optical concentrating elements being operably coupled to at least one of the plurality of photovoltaic strips;
coupling the first substrate member to the second substrate member to form an interface region along a peripheral region of the first substrate member and the second substrate member; and
sealing the interface region to form an individual solar cell from the first substrate and the second substrate.

2. The method of claim 1 wherein the optical elastomer material is a liquid.

3. The method of claim 1 further comprising curing the optical elastomer material to change a state of the optical elastomer material from a first state to a second state.

4. The method of claim 1 wherein the sealing is provided by ultrasonic welding.

5. The method of claim 1 wherein the sealing is provided by a vibrational welding.

6. The method of claim 1 wherein the sealing is provided by a thermal process.

7. The method of claim 1 wherein the sealing is provided by a chemical process.

8. The method of claim 1 wherein the sealing is provided by a glue material.

9. The method of claim 1 wherein the sealing is provided by an irradiation process.

10. The method of claim 1 wherein the plurality of photovoltaic strips are provided within respective plurality of recessed regions on the first substrate member.

11. The method of claim 1 wherein each of the strips comprises a silicon bearing material.

12. The method of claim 1 wherein the first substrate member comprises a polymer bearing material.

13. The method of claim 1 wherein the first substrate member comprises a non-conductive material.

14. The method of claim 1 wherein the first substrate member comprises a multilayered material.

15. The method of claim 1 wherein the first substrate member is optically transparent.

16. The method of claim 1 wherein the individual solar cell is provided in a panel.

17. A method for fabricating a solar cell, the method comprising: providing a first substrate member comprising a plurality of photovoltaic regions thereon; providing an encapsulating material overlying a portion of the first substrate member; aligning a second substrate member to the first substrate member, coupling the first substrate member to the second substrate member to form an interface region along a peripheral region of the first substrate member and the second substrate member; and sealing the interface region to form an individual solar cell structure from the first substrate and the second substrate.

18. The method of claim 17 wherein the encapsulating material comprises an optical elastomer material comprising a liquid.

19. A solar cell device structure comprising:
a back cover member, the back cover member having a surface area and a back area;
a plurality of photovoltaic regions disposed overlying the surface area of the back cover member, the plurality of photovoltaic regions occupying a total photovoltaic spatial region;
an encapsulating material overlying a portion of the back cover member;
a front cover member coupled to the encapsulating material;
an interface region along at least a peripheral region of the back cover member and the front cover member; and
a sealed region formed on at least the interface region to form an individual solar cell from the back cover member and the front cover member;
whereupon the total photovoltaic spatial region/the surface area of the back cover is at a ratio of about 0.80 and less for the individual solar cell.

20. A solar cell device comprising:
a first substrate member;
a plurality of photovoltaic strips overlying the first substrate member;
an encapsulant material overlying a portion of the first substrate member;
a first refractive index characterizing the encapsulant material;
a second substrate member comprising a plurality of optical concentrating elements thereon, the second substrate member overlying the plurality of photovoltaic strips such that at least one of the optical concentrating elements being operably coupled to at least one of the one of the plurality of photovoltaic strips, the plurality of concentrating elements being composed by at least a second substrate material; and
a second refractive index characterizing the second substrate material, the second refractive index being substantially matched to the first refractive index to cause one or more photons to traverse through at least one of the optical concentrating elements through a portion of the encapsulant and to a portion of one of the photovoltaic strips to reduce an amount of internal reflection from a portion of the one concentrating element.
